(19) United States
(12) Patent Application Publication
(10) Pub. No.: US 2019/0068118 A1
(43) Pub. Date: Feb. 28, 2019

(54) METHOD AND APPARATUS FOR ESTIMATING PHOTOVOLTAIC POWER GENERATION

(71) Applicant: Encored Technologies, Inc., Seoul (KR)

(72) Inventors: Hyoseop Lee, Seoul (KR); Seonjeong Lee, Seoul (KR)

(21) Appl. No.: 15/857,024

(22) Filed: Dec. 28, 2017

(30) Foreign Application Priority Data
Aug. 31, 2017 (KR) 10-2017-0110882

(51) Int. Cl. H02S 50/00; G01R 21/133; G01W 1/02

(52) U.S. Cl. CPC H02S 50/00; G01W 1/02; G01R 21/133

(57) ABSTRACT

A photovoltaic power output estimating apparatus and method are provided. The photovoltaic power output estimating apparatus includes a sensor unit configured to provide location information regarding a location where a solar panel has been or will be installed, installation angle information of the solar panel, and installation direction information of the solar panel; a camera unit configured to provide solar radiation obstruction information regarding an object obstructing solar radiation; and a specification input unit configured to receive solar panel specification information and inverter specification information based on external input.

### CROSS-REFERENCE TO RELATED APPLICATION

This application claims the benefit of Korean Patent Application No. 10-2017-0110882, filed on Aug. 31, 2017, in the Korean Intellectual Property Office, the disclosure of which is incorporated herein in its entirety by reference.

### BACKGROUND

The present invention relates to a method and apparatus for estimating photovoltaic power output, and more particularly, to a method and apparatus for estimating photovoltaic power output of a solar panel based on information provided from a sensor unit, a camera unit, a specification input unit, etc.

With the rise of global environmental issues, alternative energy technology such as photovoltaic power generation has been actively developed. Photovoltaic power generation has taken center stage as clean and environment friendly alternative energy and photovoltaic installation capacity has been increasing continuously. In particular, installation of home solar panels for houses and apartments has recently been increasing every year.

Photovoltaic power generation is influenced by meteorological conditions such as solar radiation and temperature, a location of a solar panel, an inclination angle of the solar panel, etc. Accordingly, a technique of acquiring information influencing photovoltaic power output and a technique of estimating photovoltaic power output based on the acquired information are needed when a solar panel is installed.

### SUMMARY

This work was supported by the Korea Institute of Energy Technology Evaluation and Planning (KETEP) and the Ministry of Trade, Industry and Energy (MOTIE) of the Republic of Korea (No. 20161210200410).

The present invention provides a method and apparatus for estimating photovoltaic power output of a solar panel based on information provided from a sensor unit, a camera unit, a specification input unit, etc. and a computer-readable recording medium having recorded thereon a program for executing the method.

According to an aspect of an exemplary embodiment, there is provided a method of estimating photovoltaic power output. The method includes providing location information regarding a location where a solar panel has been or will be installed, installation angle information of the solar panel, and installation direction information of the solar panel; providing solar radiation obstruction information regarding an object obstructing solar radiation; and receiving solar panel specification information and inverter specification information based on external input.

The providing of the location information, the installation angle information, and the installation direction information may be performed by a location sensor and a geomagnetic sensor.

The solar panel specification information may include surface permeability of the solar panel and generating efficiency of the solar panel.

The inverter specification information may include inverter conversion efficiency indicating power loss occurring during conversion from direct current (DC) power accumulated through the solar panel into alternating current (AC) power.

The method may further include acquiring meteorological information from a meteorological information database based on the location information.

The meteorological information may include at least one among temperature, humidity, wind velocity, wind direction, and cloud amount at the location where the solar panel will be installed.

The method may further include calculating a solar elevation angle between the sun and the solar panel based on the location information; calculating solar radiation at the installation location of the solar panel based on the meteorological information and the solar radiation obstruction information; calculating solar radiation on an inclined plane of the solar panel based on the solar elevation angle, the solar radiation at the installation location, the installation angle information, and the installation direction information; and calculating photovoltaic power output based on the solar radiation on the inclined plane, the solar panel specification information, and the inverter specification information.

The calculating of the solar radiation on the inclined plane may include calculating a rate of obstructed solar radiation at the installation location of the solar panel based on the solar radiation obstruction information.

The calculating of the photovoltaic power output may include calculating DC power output based on the solar radiation on the inclined plane and the solar panel specification information and calculating AC power output based on the DC power output and the inverter specification information.

The method may further include transmitting the location information, the installation angle information, the installation direction information, the solar radiation obstruction information, the solar panel specification information, and the inverter specification information to an information processing apparatus configured to calculate the photovoltaic power output.

According to an aspect of another exemplary embodiment, there is provided an information processing method including receiving location information regarding a location where a solar panel has been or will be installed, installation angle information of the solar panel, installation direction information of the solar panel, solar radiation obstruction information regarding an object obstructing solar radiation, solar panel specification information, and inverter specification information from an information acquiring apparatus configured to provide information for calculation of photovoltaic power output; acquiring meteorological information from a meteorological information database or the information acquiring apparatus based on the location information; calculating a solar elevation angle between the sun and the solar panel based on the location information; calculating solar radiation at the installation location of the solar panel based on the meteorological information and the solar radiation obstruction information; calculating solar radiation on an inclined plane of the solar panel based on the solar elevation angle, the solar radiation at the installation location, the installation angle information, and the installation direction information; and calculating the photovoltaic power output based on the solar radiation on the inclined plane, the solar panel specification information, and the inverter specification information.

The solar panel specification information may include surface permeability of the solar panel and generating efficiency of the solar panel.

The inverter specification information may include inverter conversion efficiency indicating power loss occurring during conversion from DC power accumulated through the solar panel into AC power.

The meteorological information may include at least one among temperature, humidity, wind velocity, wind direction and cloud amount at the location where the solar panel will be installed.

The calculating of the solar radiation on the inclined plane may include calculating a rate of obstructed solar radiation at the installation location of the solar panel based on the solar radiation obstruction information.

The calculating of the photovoltaic power output may include calculating DC power output based on the solar radiation on the inclined plane and the solar panel specification information and calculating AC power output based on the DC power output and the inverter specification information.

According to an aspect of another exemplary embodiment, there is provided a computer-readable recording medium having recorded thereon a program for executing any one of the above-described methods.

According to an aspect of another exemplary embodiment, there is provided a photovoltaic power output estimating apparatus including a sensor unit configured to provide location information regarding a location where a solar panel has been or will be installed, installation angle information of the solar panel, and installation direction information of the solar panel; a camera unit configured to provide solar radiation obstruction information regarding an object obstructing solar radiation; and a specification input unit configured to receive solar panel specification information and inverter specification information based on external input.

According to an aspect of another exemplary embodiment, there is provided an information processing apparatus including a communication unit configured to receive location information regarding a location where a solar panel has been or will be installed, installation angle information of the solar panel, installation direction information of the solar panel, solar radiation obstruction information regarding an object obstructing solar radiation, solar panel specification information, and inverter specification information from an information acquiring apparatus configured to provide information for calculation of photovoltaic power output; a meteorological information acquiring unit configured to acquire meteorological information from a meteorological information database or the information acquiring apparatus based on the location information; a solar radiation calculator configured to calculate a solar elevation angle between the sun and the solar panel based on the location information, to calculate solar radiation at the installation location of the solar panel based on the meteorological information and the solar radiation obstruction information, and to calculate solar radiation on an inclined plane of the solar panel based on the solar elevation angle, the solar radiation at the installation location, the installation angle information, and the installation direction information; and a power output calculator configured to calculate photovoltaic power output based on the solar radiation on the inclined plane, the solar panel specification information, and the inverter specification information.

### BRIEF DESCRIPTION OF THE DRAWINGS

Embodiments of the present invention will be more clearly understood from the following detailed description taken in conjunction with the accompanying drawings in which:

FIG. 1 is a diagram of a photovoltaic power output estimating apparatus according to some embodiments of the present invention;

FIG. 2 is a block diagram of a photovoltaic power output estimating apparatus according to some embodiments of the present invention;

FIG. 3 is a flowchart of a method of estimating photovoltaic power output according to some embodiments of the present invention;

FIG. 4 is a flowchart of a method of calculating solar radiation on a solar panel's inclined plane according to some embodiments of the present invention; and

FIG. 5 is a block diagram of a photovoltaic power output estimating system according to some embodiments of the present invention.

### DETAILED DESCRIPTION OF THE EMBODIMENTS

Hereinafter, embodiments of the present invention will be described in detail with reference to the accompanying drawings in which like numbers refer to like elements and the sizes of elements may be exaggerated for clarity.

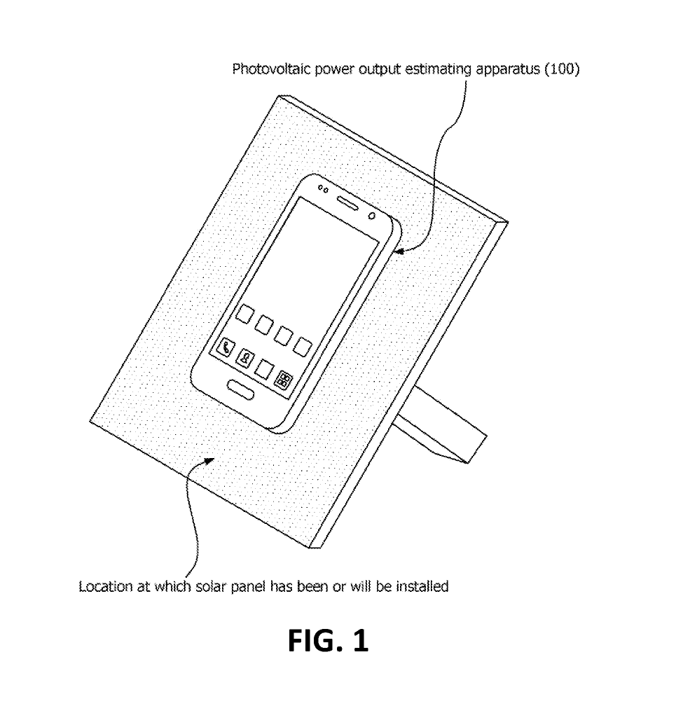

FIG. 1 is a diagram of a photovoltaic power output estimating apparatus according to some embodiments of the present invention.

According to the current embodiments, a photovoltaic power output estimating apparatus 100 may be placed at a location where a solar panel has been or will be installed and may acquire meteorological information from a meteorological information database accessible through the Internet, receive solar panel specification information and inverter specification information from a user, and precisely estimate photovoltaic power output. Since the photovoltaic power output estimating apparatus 100 includes a sensor unit including a location sensor and a geomagnetic sensor, the photovoltaic power output estimating apparatus 100 may acquire information about a location at which a solar panel has been or will be installed, installation angle information of the solar panel, and installation direction information of the solar panel, without a special sensor or external input.

Consequently, when the photovoltaic power output estimating apparatus 100 is placed at a location where a solar panel has been or will be installed and the angle and direction of the photovoltaic power output estimating apparatus 100 are adjusted, the photovoltaic power output estimating apparatus 100 may estimate past or future photovoltaic power output without additional special input, so that optimal installation location and position of the solar panel may be determined and the estimated power output may be used to decide whether or not to install the solar panel and may also be used for an economic analysis of the solar panel.

The photovoltaic power output estimating apparatus 100 is implemented as a mobile terminal, such as a smartphone or a tablet computer, in the current embodiments. However, it is apparent to those skilled in the art that the photovoltaic power output estimating apparatus 100 may be implemented as other types of devices.

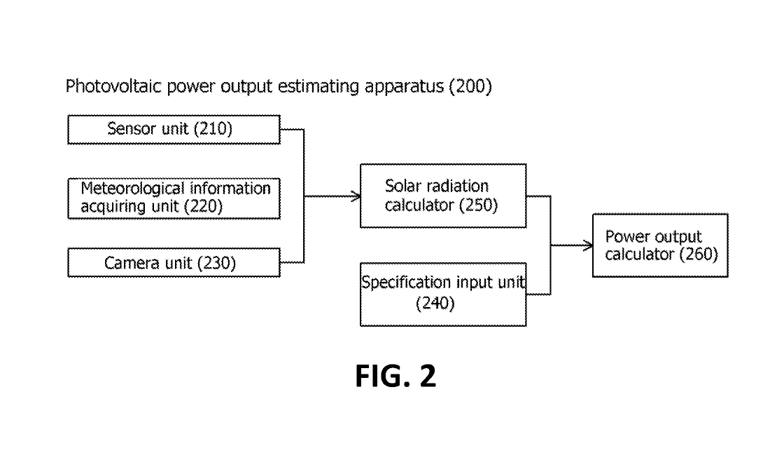

FIG. 2 is a block diagram of a photovoltaic power output estimating apparatus according to some embodiments of the present invention.

According to the current embodiments, a photovoltaic power output estimating apparatus 200 includes a sensor unit 210, a meteorological information acquiring unit 220, a camera unit 230, a specification input unit 240, a solar radiation calculator 250, and a power output calculator 260.

The sensor unit 210 provides information about a location where a solar panel has been or will be installed, i.e., location information, installation angle information of the solar panel, and installation direction information of the solar panel. The sensor unit 210 includes a location sensor and a geomagnetic sensor. The sensor unit 210 acquires the location information including latitude and longitude of the location where the solar panel has been or will be installed through the location sensor. The sensor unit 210 acquires the installation angle information and the installation direction information of the solar panel through the location sensor and the geomagnetic sensor.

The meteorological information acquiring unit 220 acquires meteorological information from a meteorological information database based on the location information. The meteorological information includes at least one among temperature, humidity, wind velocity, wind direction, and cloud amount at the installation location of the solar panel. The meteorological information acquiring unit 220 acquires the meteorological information from the meteorological information database through Internet communication.

The camera unit 230 provides solar radiation obstruction information. The solar radiation obstruction information is information about an object which obstructs solar radiation. The object is captured by the camera unit 230. For example, when there is a building partially hiding the sun from the installation location of the solar panel, solar radiation may be obstructed by the building.

The specification input unit 240 receives solar panel specification information and inverter specification information based on external input.

The solar panel specification information includes surface permeability of a solar panel and generating efficiency thereof. The surface permeability of a solar panel is a rate of sunlight absorbed by the solar panel. The generating efficiency of a solar panel is a rate of converting sunlight absorbed by the solar panel into electricity. According to some embodiments, a user may select a solar panel product of which the specification information has already been input to the specification input unit 240 or may directly input the solar panel specification information to the specification input unit 240.

The inverter specification information is inverter conversion efficiency indicating power loss occurring during conversion from direct current (DC) power into alternating current (AC) power. Since power accumulated using a solar panel is DC power, an inverter converts the DC power into AC power, i.e., an electricity form normally used. At this time, power loss occurs based on the inverter conversion efficiency, and therefore, the power output calculator 260, which will be described below, reflects the power loss in calculation of power output. According to some embodiments, a user may select an inverter product of which the specification information has already been input to the specification input unit 240 or may directly input the inverter specification information to the specification input unit 240.

The solar radiation calculator 250 calculates solar radiation on the inclined plane of the solar panel.

In detail, the solar radiation calculator 250 calculates a solar elevation angle between the sun and the solar panel based on the location information.

The solar radiation calculator 250 calculates solar radiation at the installation location of the solar panel based on the meteorological information and the solar radiation obstruction information. In detail, the solar radiation calculator 250 calculates a rate of obstructed solar radiation at the installation location of the solar panel based on information of an object, which has been captured by the camera unit 230 as a solar radiation obstruction, and calculates solar radiation at the installation location based on the obstruction rate and the meteorological information.

The solar radiation calculator 250 calculates solar radiation on the inclined plane of the solar panel based on the solar elevation angle, the solar radiation at the installation location of the solar panel, and the installation angle information and the installation direction information of the solar panel.

The power output calculator 260 calculates photovoltaic power output based on the solar radiation on the inclined plane of the solar panel, the solar panel specification information, and the inverter specification information. The power output calculator 260 calculates DC power output based on the solar radiation on the solar panel's inclined plane and the solar panel specification information and calculates AC power output based on the DC power output and the inverter specification information.

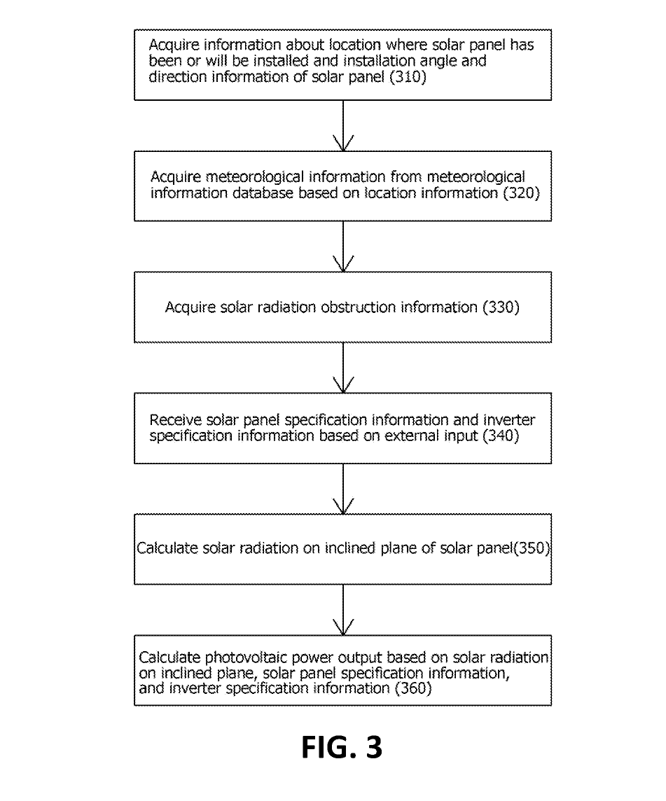

FIG. 3 is a flowchart of a method of estimating photovoltaic power output according to some embodiments of the present invention.

The photovoltaic power output estimating apparatus 200 acquires information about a location where a solar panel has been or will be installed, i.e., location information, installation angle information of the solar panel, and installation direction information of the solar panel in operation 310.

The photovoltaic power output estimating apparatus 200 acquires meteorological information from a meteorological information database based on the location information in operation 320.

The photovoltaic power output estimating apparatus 200 acquires solar radiation obstruction information in operation 330.

The photovoltaic power output estimating apparatus 200 receives solar panel specification information and inverter specification information based on external input in operation 340.

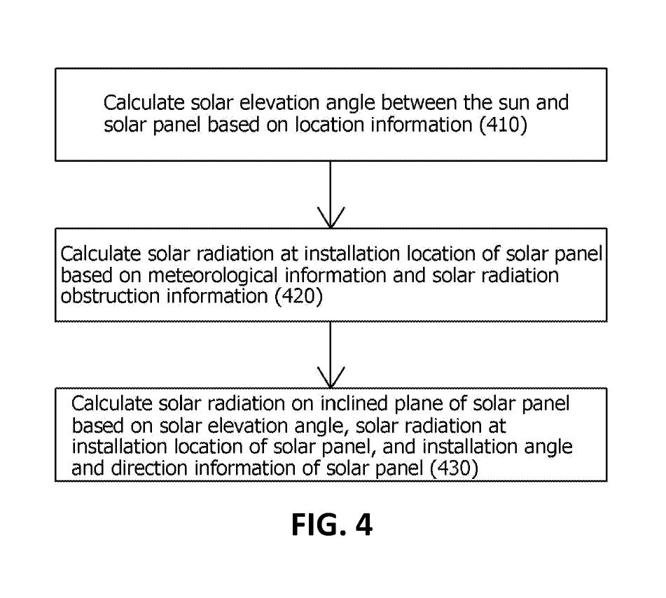

The photovoltaic power output estimating apparatus 200 calculates solar radiation on the inclined plane of the solar panel in operation 350. A method of calculating the solar radiation on the solar panel's inclined plane will be described in detail with reference to FIG. 4 below.

The photovoltaic power output estimating apparatus 200 calculates photovoltaic power output based on the solar radiation on the solar panel's inclined plane, the solar panel specification information, and the inverter specification information in operation 360.

FIG. 4 is a flowchart of a method of calculating solar radiation on a solar panel's inclined plane according to some embodiments of the present invention.

The photovoltaic power output estimating apparatus 200 calculates a solar elevation angle between the sun and the solar panel based on the location information of the solar panel in operation 410.

The photovoltaic power output estimating apparatus 200 calculates solar radiation at the installation location of the solar panel based on the meteorological information and the solar radiation obstruction information in operation 420.

The photovoltaic power output estimating apparatus 200 calculates the solar radiation on the solar panel's inclined plane based on the solar elevation angle, solar radiation at the installation location of the solar panel, and the installation angle information and the installation direction information of the solar panel in operation 430.

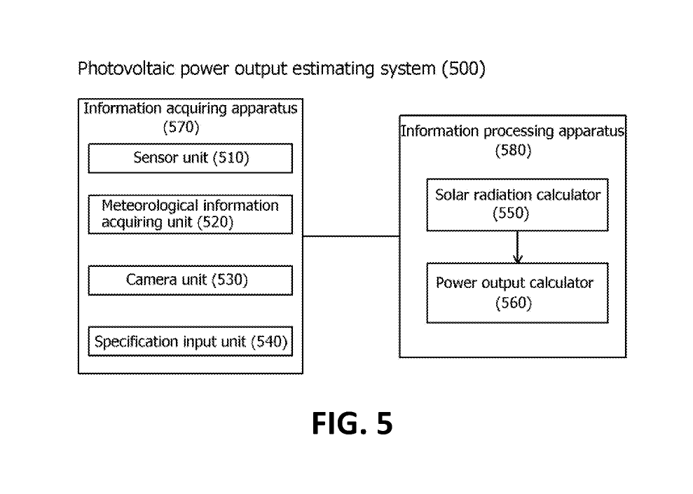

FIG. 5 is a block diagram of a photovoltaic power output estimating system 500 according to some embodiments of the present invention.

The photovoltaic power output estimating system 500 includes an information acquiring apparatus 570 and an information processing apparatus 580. The information acquiring apparatus 570 acquires information, such as location information, solar radiation obstruction information, and meteorological information, necessary for the estimation of photovoltaic power output and transmits the information necessary for the photovoltaic power output estimation to the information processing apparatus 580. The information processing apparatus 580 receives the information necessary for the photovoltaic power output estimation from the information acquiring apparatus 570 and calculates photovoltaic power output. The information acquiring apparatus 570 may be implemented as a mobile terminal such as a smartphone or a tablet computer, but it is apparent to those skilled in the art that the information acquiring apparatus 570 may be implemented as any type of device that provides information necessary for the estimation of photovoltaic power output. The information processing apparatus 580 may be implemented as a server, but it is apparent to those skilled in the art that the information processing apparatus 580 may be implemented as any type of device that calculates photovoltaic power output.

The information acquiring apparatus 570 includes a sensor unit 510, a meteorological information acquiring unit 520, a camera unit 530, and a specification input unit 540.

The sensor unit 510 provides information about a location where a solar panel has been or will be installed, i.e., location information, installation angle information of the solar panel, and installation direction information of the solar panel. The sensor unit 510 includes a location sensor and a geomagnetic sensor. The sensor unit 510 acquires the location information including latitude and longitude of a location where the solar panel has been or will be installed through the location sensor. The sensor unit 510 acquires the installation angle information and the installation direction information of the solar panel through the location sensor and the geomagnetic sensor.

The meteorological information acquiring unit 520 acquires meteorological information from a meteorological information database based on the location information. The meteorological information includes at least one among temperature, humidity, wind velocity, wind direction, and cloud amount at the location of the solar panel. The meteorological information acquiring unit 520 acquires the meteorological information from the meteorological information database through Internet communication.

The camera unit 530 provides solar radiation obstruction information, i.e., information about an object which obstructs solar radiation.

The specification input unit 540 receives solar panel specification information and inverter specification information based on external input. The solar panel specification information includes surface permeability of a solar panel and generating efficiency thereof. According to some embodiments, a user may select a solar panel product of which the specification information has already been input to the specification input unit 540 or may directly input the solar panel specification information to the specification input unit 540. The inverter specification information is inverter conversion efficiency indicating power loss occurring during conversion from DC power into AC power. According to some embodiments, a user may select an inverter product of which the specification information has already been input to the specification input unit 540 or may directly input the inverter specification information to the specification input unit 540.

The information acquiring apparatus 570 may also include a communication unit. The communication unit transmits the location information, the installation angle information, the installation direction information, the solar radiation obstruction information, the meteorological information, the solar panel specification information, and the inverter specification information to the information processing apparatus 580.

The information processing apparatus 580 includes a communication unit, a solar radiation calculator 550, and a power output calculator 560.

The communication unit receives the location information, the installation angle information, the installation direction information, the solar radiation obstruction information, the meteorological information, the solar panel specification information, and the inverter specification information from the information acquiring apparatus 570.

The solar radiation calculator 550 calculates solar radiation on the inclined plane of the solar panel. In detail, the solar radiation calculator 550 calculates a solar elevation angle between the sun and the solar panel based on the location information. The solar radiation calculator 550 calculates solar radiation at the installation location of the solar panel based on the meteorological information and the solar radiation obstruction information. In detail, the solar radiation calculator 550 calculates a rate of obstructed solar radiation at the solar panel installation location based on information of an object, which has been captured by the camera unit 230 as a solar radiation obstruction, and calculates solar radiation at the installation location of the solar panel based on the obstruction rate and the meteorological information. The solar radiation calculator 550 calculates solar radiation on the inclined plane of the solar panel based on the solar elevation angle, the solar radiation at the installation location of the solar panel, and the installation angle information and the installation direction information of the solar panel.

The power output calculator 560 calculates photovoltaic power output based on the solar radiation on the inclined plane of the solar panel, the solar panel specification information, and the inverter specification information. The power output calculator 560 calculates DC power output based on the solar radiation on the solar panel's inclined plane and the solar panel specification information and calculates AC power output based on the DC power output and the inverter specification information.

According to other embodiments of the present invention, a photovoltaic power output estimating system includes an information acquiring apparatus and an information processing apparatus. The information acquiring apparatus acquires information, such as location information, necessary for the estimation of photovoltaic power output and transmits the information necessary for the photovoltaic power output estimation to the information processing apparatus. The information processing apparatus receives the information such as the location information necessary for the photovoltaic power output estimation from the information acquiring apparatus, acquires meteorological information from a meteorological information database based on the location information, and calculates photovoltaic power output. The information acquiring apparatus may be implemented as a mobile terminal such as a smartphone or a tablet computer, but it is apparent to those skilled in the art that the information acquiring apparatus may be implemented as any type of device that provides information necessary for the estimation of photovoltaic power output. The information processing apparatus may be implemented as a server, but it is apparent to those skilled in the art that the information processing apparatus may be implemented as any type of device that calculates photovoltaic power output.

The information acquiring apparatus includes a sensor unit, a camera unit, and a specification input unit. The structure and operations of the sensor unit, the camera unit, and the specification input unit are the same as those described above with reference to FIG. 5.

The information acquiring apparatus may also include a communication unit. The communication unit transmits information about a location where a solar panel has been or will be installed, i.e., location information, installation angle information of the solar panel, installation direction information of the solar panel, solar radiation obstruction information, solar panel specification information, and inverter specification information to the information processing apparatus.

The information processing apparatus includes a communication unit, a meteorological information acquiring unit, a solar radiation calculator, and a power output calculator.

The communication unit receives the location information, the installation angle information, the installation direction information, the solar radiation obstruction information, the solar panel specification information, and the inverter specification information from the information acquiring apparatus.

The meteorological information acquiring unit acquires meteorological information from a meteorological information database based on the location information. The meteorological information includes at least one among temperature, humidity, wind velocity, wind direction, and cloud amount at the location of the solar panel. The meteorological information acquiring unit acquires the meteorological information from the meteorological information database through Internet communication.

The solar radiation calculator calculates solar radiation on the inclined plane of the solar panel. In detail, the solar radiation calculator calculates a solar elevation angle between the sun and the solar panel based on the location information. The solar radiation calculator calculates solar radiation at the installation location of the solar panel based on the meteorological information and the solar radiation obstruction information. In detail, the solar radiation calculator calculates a rate of obstructed solar radiation at the installation location of the solar panel based on information of an object, which has been captured by the camera unit as a solar radiation obstruction, and calculates solar radiation at the installation location of the solar panel based on the obstruction rate and the meteorological information. The solar radiation calculator calculates solar radiation on the inclined plane of the solar panel based on the solar elevation angle, the solar radiation at the installation location of the solar panel, and the installation angle information and installation direction information of the solar panel.

The power output calculator calculates photovoltaic power output based on the solar radiation on the inclined plane of the solar panel, the solar panel specification information, and the inverter specification information. The power output calculator calculates DC power output based on the solar radiation on the solar panel's inclined plane and the solar panel specification information and calculates AC power output based on the DC power output and the inverter specification information.

According to some embodiments of the present invention, a photovoltaic power output estimating apparatus may be placed at a location where a solar panel has been or will be installed and may acquire meteorological information from a meteorological information database accessible through the Internet, may receive solar panel specification information and inverter specification information from a user, and may precisely estimate photovoltaic power output. Accordingly, when the photovoltaic power output estimating apparatus is placed at a location where a solar panel has been or will be installed and the angle and direction of the photovoltaic power output estimating apparatus are adjusted, the photovoltaic power output estimating apparatus may estimate past or future photovoltaic power output without additional special input, so that optimal installation location and position of the solar panel may be determined and the estimated power output may be used to decide whether or not to install the solar panel and may be used for an economic analysis of the solar panel.

While the present invention has been particularly shown and described with reference to embodiments thereof, it will be understood that various changes in form and details may be made therein without departing from the spirit and scope of the following claims.

For example, an apparatus according to some embodiments of the present invention may also include a bus connected to each element of the apparatus shown in the drawings, at least one processor connected to the bus, and memory connected to the bus to store commands, received messages, or generated messages. The memory is also connected to the at least one processor which executes the commands.

The present invention can also be embodied as computer readable codes on a computer readable recording medium. The computer readable recording medium is any data storage device that can store data which can be thereafter read by a computer system. Examples of the computer readable recording medium include magnetic storage media (e.g., ROM, floppy disks, hard disks, etc.) and optical recording media (e.g., CD-ROMs, or DVDs). The computer readable recording medium can also be distributed over network coupled computer systems so that the computer readable code is stored and executed in a distributed fashion.

The present invention may be embodied in other specific forms without departing from its spirit or essential characteristics. The described embodiments are to be considered in all respects only as illustrative and not restrictive. The scope of the invention will be, therefore, indicated by claims rather than by the foregoing description. All changes which come within the meaning and range of equivalency of the claims are to be embraced within their scope.

What is claimed is:

1. A photovoltaic power output estimating apparatus comprising:
a sensor unit configured to provide location information regarding a location where a solar panel has been or will be installed, installation angle information of the solar panel, and installation direction information of the solar panel;
a camera unit configured to provide solar radiation obstruction information regarding an object obstructing solar radiation; and
a specification input unit configured to receive solar panel specification information and inverter specification information based on external input.

2. The photovoltaic power output estimating apparatus of claim 1, wherein the sensor unit comprises a location sensor and a geomagnetic sensor.

3. The photovoltaic power output estimating apparatus of claim 1, wherein the solar panel specification information comprises surface permeability of the solar panel and generating efficiency of the solar panel.

4. The photovoltaic power output estimating apparatus of claim 1, wherein the inverter specification information comprises inverter conversion efficiency indicating power loss occurring during conversion from direct current (DC) power accumulated through the solar panel into alternating current (AC) power.

5. The photovoltaic power output estimating apparatus of claim 1, further comprising a meteorological information acquiring unit configured to acquire meteorological information from a meteorological information database based on the location information.

6. The photovoltaic power output estimating apparatus of claim 5, wherein the meteorological information comprises at least one among temperature, humidity, wind velocity, wind direction, and cloud amount at the location where the solar panel will be installed.

7. The photovoltaic power output estimating apparatus of claim 5, further comprising:
a solar radiation calculator configured to calculate a solar elevation angle between the sun and the solar panel based on the location information, to calculate solar radiation at the installation location of the solar panel based on the meteorological information and the solar radiation obstruction information, and to calculate solar radiation on an inclined plane of the solar panel based on the solar elevation angle, the solar radiation at the installation location, the installation angle information, and the installation direction information; and
a power output calculator configured to calculate photovoltaic power output based on the solar radiation on the inclined plane, the solar panel specification information, and the inverter specification information.

8. The photovoltaic power output estimating apparatus of claim 7, wherein the solar radiation calculator calculates a rate of obstructed solar radiation at the installation location of the solar panel based on the solar radiation obstruction information.

9. The photovoltaic power output estimating apparatus of claim 7, wherein the power output calculator calculates direct current (DC) power output based on the solar radiation on the inclined plane and the solar panel specification information and calculates alternating current (AC) power output based on the DC power output and the inverter specification information.

10. The photovoltaic power output estimating apparatus of claim 1, further comprising a communication unit configured to transmit the location information, the installation angle information, the installation direction information, the solar radiation obstruction information, the solar panel specification information, and the inverter specification information to an information processing apparatus configured to calculate photovoltaic power output.

11. An information processing apparatus comprising:
a communication unit configured to receive location information regarding a location where a solar panel has been or will be installed, installation angle information of the solar panel, installation direction information of the solar panel, solar radiation obstruction information regarding an object obstructing solar radiation, solar panel specification information, and inverter specification information from an information acquiring apparatus configured to provide information necessary for calculation of photovoltaic power output;
a meteorological information acquiring unit configured to acquire meteorological information from a meteorological information database or the information acquiring apparatus based on the location information;
a solar radiation calculator configured to calculate a solar elevation angle between the sun and the solar panel based on the location information, to calculate solar radiation at the installation location of the solar panel based on the meteorological information and the solar radiation obstruction information, and to calculate solar radiation on an inclined plane of the solar panel based on the solar elevation angle, the solar radiation at the installation location, the installation angle information, and the installation direction information; and
a power output calculator configured to calculate photovoltaic power output based on the solar radiation on the inclined plane, the solar panel specification information, and the inverter specification information.

12. The information processing apparatus of claim 11, wherein the solar panel specification information comprises surface permeability of the solar panel and generating efficiency of the solar panel.

13. The information processing apparatus of claim 11, wherein the inverter specification information comprises inverter conversion efficiency indicating power loss occurring during conversion from direct current (DC) power accumulated through the solar panel into alternating current (AC) power.

14. The information processing apparatus of claim 11, wherein the meteorological information comprises at least one among temperature, humidity, wind velocity, wind direction, and cloud amount at the location where the solar panel will be installed.

15. The information processing apparatus of claim 11, wherein the solar radiation calculator calculates a rate of obstructed solar radiation at the installation location of the solar panel based on the solar radiation obstruction information.

16. The information processing apparatus of claim 11, wherein the power output calculator calculates direct current (DC) power output based on the solar radiation on the inclined plane and the solar panel specification information and calculates alternating current (AC) power output based on the DC power output and the inverter specification information.

17. A method of estimating photovoltaic power output, the method comprising:
providing location information regarding a location where a solar panel has been or will be installed, installation angle information of the solar panel, and installation direction information of the solar panel;
providing solar radiation obstruction information regarding an object obstructing solar radiation; and
receiving solar panel specification information and inverter specification information based on external input.

18. The method of claim 17, wherein the providing of the location information, the installation angle information, and the installation direction information is performed by a location sensor and a geomagnetic sensor.

19. The method of claim 17, wherein the solar panel specification information comprises surface permeability of the solar panel and generating efficiency of the solar panel.

20. The method of claim 17, wherein the inverter specification information comprises inverter conversion efficiency indicating power loss occurring during conversion from direct current (DC) power accumulated through the solar panel into alternating current (AC) power.

21. The method of claim 17, further comprising acquiring meteorological information from a meteorological information database based on the location information.

22. The method of claim 21, wherein the meteorological information comprises at least one among temperature, humidity, wind velocity, wind direction, and cloud amount at the location where the solar panel will be installed.

23. The method of claim 21, further comprising:
calculating a solar elevation angle between the sun and the solar panel based on the location information;
calculating solar radiation at the installation location of the solar panel based on the meteorological information and the solar radiation obstruction information;
calculating solar radiation on an inclined plane of the solar panel based on the solar elevation angle, the solar radiation at the installation location, the installation angle information, and the installation direction information; and
calculating photovoltaic power output based on the solar radiation on the inclined plane, the solar panel specification information, and the inverter specification information.

24. The method of claim 23, wherein the calculating of the solar radiation on the inclined plane comprises calculating a rate of obstructed solar radiation at the installation location of the solar panel based on the solar radiation obstruction information.

25. The method of claim 23, wherein the calculating of the photovoltaic power output comprises:
calculating direct current (DC) power output based on the solar radiation on the inclined plane and the solar panel specification information; and
calculating alternating current (AC) power output based on the DC power output and the inverter specification information.

26. The method of claim 17, further comprising transmitting the location information, the installation angle information, the installation direction information, the solar radiation obstruction information, the solar panel specification information, and the inverter specification information to an information processing apparatus configured to calculate the photovoltaic power output.

27. An information processing method comprising:
receiving location information regarding a location where a solar panel has been or will be installed, installation angle information of the solar panel, installation direction information of the solar panel, solar radiation obstruction information regarding an object obstructing solar radiation, solar panel specification information, and inverter specification information from an information acquiring apparatus configured to provide information necessary for calculation of photovoltaic power output;
acquiring meteorological information from a meteorological information database or the information acquiring apparatus based on the location information;
calculating a solar elevation angle between the sun and the solar panel based on the location information;
calculating solar radiation at the installation location of the solar panel based on the meteorological information and the solar radiation obstruction information;
calculating solar radiation on an inclined plane of the solar panel based on the solar elevation angle, the solar radiation at the installation location, the installation angle information, and the installation direction information; and
calculating the photovoltaic power output based on the solar radiation on the inclined plane, the solar panel specification information, and the inverter specification information.

28. The information processing method of claim 27, wherein the solar panel specification information comprises surface permeability of the solar panel and generating efficiency of the solar panel.

29. The information processing method of claim 27, wherein the inverter specification information comprises inverter conversion efficiency indicating power loss occurring during conversion from direct current (DC) power accumulated through the solar panel into alternating current (AC) power.

30. The information processing method of claim 27, wherein the meteorological information comprises at least one among temperature, humidity, wind velocity, wind direction, and cloud amount at the location where the solar panel will be installed.

31. The information processing method of claim 27, wherein the calculating of the solar radiation on the inclined plane comprises calculating a rate of obstructed solar radiation at the installation location of the solar panel based on the solar radiation obstruction information.

32. The information processing method of claim 27, wherein the calculating of the photovoltaic power output comprises:
calculating direct current (DC) power output based on the solar radiation on the inclined plane and the solar panel specification information; and
calculating alternating current (AC) power output based on the DC power output and the inverter specification information.
